(19) United States
(12) Patent Application Publication
(10) Pub. No.: US 2025/0374768 A1
(43) Pub. Date: Dec. 4, 2025

(54) DISPLAY DEVICE

(71) Applicant: Samsung Display Co., LTD., Yongin-si (KR)

(72) Inventors: Soo Yeong HONG, Yongin-si (KR); Kwang Soo BAE, Yongin-si (KR); Hyang A PARK, Yongin-si (KR); Bo Kwang SONG, Yongin-si (KR)

(21) Appl. No.: 19/075,536

(22) Filed: Mar. 10, 2025

(30) Foreign Application Priority Data
Jun. 3, 2024 (KR) 10-2024-0072419

(51) Int. Cl. H10K 59/122; H10K 39/30

(52) U.S. Cl. CPC H10K 59/122; H10K 39/30

(57) ABSTRACT

A display device includes: first light-emitting areas to emit light of a first color; second light-emitting areas to emit light of a second color different from the first color; third light-emitting areas to emit light of a third color different from the second color; a sensor area between second light-emitting areas adjacent to each other in a first direction from among the second light-emitting areas; a pixel defining layer defining the first, second, and third light-emitting areas, and the sensor area; first separation portions surrounding around a half or more of an edge of each of the first to third light-emitting areas; and second separation portions surrounding around a half or more of an edge of the sensor area, and located on a shortest distance between one of the second light-emitting areas and the senor area that are adjacent to each other.

### CROSS-REFERENCE TO RELATED APPLICATION

The present application claims priority to and the benefit of Korean Patent Application No. 10-2024-0072419, filed on Jun. 3, 2024, in the Korean Intellectual Property Office, the entire disclosure of which is incorporated by reference herein.

### BACKGROUND

### 1. Field

Aspects of one or more embodiments of the present disclosure relate to a display device.

### 2. Description of the Related Art

With the advancement of the information age, demand for a display device for displaying an image has increased in various forms. For example, the display device has been applied to various electronic devices, such as a smart phone, a digital camera, a laptop computer, a navigator, and a smart television. The display device includes a light emitting element in which each of the pixels of a display panel may self-emit light, thereby displaying an image even without using or including a backlight unit that provides the display panel with light.

The display device may include a display panel for displaying an image, an optical sensor for sensing light, and a fingerprint sensor for sensing a person's fingerprint. As the display device has been applied to various electronic devices, display devices having various designs have been desired. For example, the display device may have a widened display area for displaying an image by removing a sensor device, such as a separate optical sensor or fingerprint sensor.

The above information disclosed in this Background section is for enhancement of understanding of the background of the present disclosure, and therefore, it may contain information that does not constitute prior art.

### SUMMARY

One or more embodiments of the present disclosure may be directed to a display device that may minimize or reduce a leakage current flowing in a fingerprint sensor, even in a high-resolution structure in which the pixels and the fingerprint sensor are concentrated, and thus, may improve a sensitivity of the fingerprint sensor.

However, the aspects and features of the present disclosure are not limited to those described above. The above and other aspects and features of the present disclosure will become more apparent to those having ordinary skill in the art from the following description and the detailed description below with reference to the drawings.

According to one or more embodiments of the present disclosure, a display device includes: a plurality of first light-emitting areas configured to emit light of a first color; a plurality of second light-emitting areas configured to emit light of a second color different from the first color; a plurality of third light-emitting areas configured to emit light of a third color different from the second color; a sensor area between second light-emitting areas adjacent to each other in a first direction from among the plurality of second light-emitting areas; a pixel defining layer defining the first, second, and third light-emitting areas, and the sensor area; a plurality of first separation portions surrounding around a half or more of an edge of each of the first to third light-emitting areas; and a plurality of second separation portions surrounding around a half or more of an edge of the sensor area, and located on a shortest distance between one of the second light-emitting areas and the senor area that are adjacent to each other.

In an embodiment, the display device may further include: a first opening portion exposing an edge of each of the first, second, and third light-emitting areas toward at least one of the first, second, or third light-emitting areas adjacent thereto; and a second opening portion exposing an edge of the sensor area toward at least one of the first or third light-emitting area adjacent thereto.

In an embodiment, the first opening portion may not be located on a shortest distance between adjacent light-emitting areas of the first, second, and third light-emitting areas.

In an embodiment, the second opening portion may not be located on a shortest distance between one of the second light-emitting areas and the senor area that are adjacent to each other.

In an embodiment, the second opening portion may be located in a second direction crossing the first direction with respect to a center of the sensor area.

In an embodiment, the sensor area may be located between the first and third light-emitting areas that are adjacent to each other in a second direction crossing the first direction.

In an embodiment, a distance between the sensor area and the second separation portion may be shorter than a distance between one of the first, second, or third light-emitting areas and the first separation portion.

In an embodiment, each of the first and second separation portions may have an embossed shape protruded from the pixel defining layer, and may have a reverse tapered angle structure having an upper width greater than a lower width.

In an embodiment, each of the first and second separation portions may have an embossed shape protruded from the pixel defining layer, and may have a tapered angle structure having an upper width smaller than a lower width. An angle between a side and a lower surface of each of the first and second separation portions may be 80° or more.

In an embodiment, the first separation portion may have an engraved shape recessed from an upper surface of the pixel defining layer, and the second separation portion may have an embossed shape protruded from the upper surface of the pixel defining layer.

In an embodiment, the display device may further include: a pixel electrode in each of the first, second, and third light-emitting areas; a sensor electrode in the sensor area, and at the same layer as that of the pixel electrode; a hole transporting layer on the pixel electrode and the sensor electrode; a light emitting layer on the hole transporting layer in each of the first, second, and third light-emitting areas; a light receiving layer on the hole transporting layer in the sensor area; an electron transporting layer on the light emitting layer and the light receiving layer; and a common electrode on the electron transporting layer.

In an embodiment, the hole transporting layer, the electron transporting layer, and the common electrode may be divided by the first and second separation portions.

In an embodiment, the display device may further include: a spacer surrounded by the first, second, and third light-emitting areas, and having an embossed shape protruded from the pixel defining layer.

In an embodiment, the spacer and the second separation portion may be located at the same layer as each other and may have the same shape as each other.

According to one or more embodiments of the present disclosure, a display device includes: a plurality of first light-emitting areas configured to emit light of a first color; a plurality of second light-emitting areas configured to emit light of a second color different from the first color, and adjacent to one another along a first direction and a second direction crossing the first direction; a plurality of third light-emitting areas configured to emit light of a third color different from the second color, spaced from each of the plurality of second light-emitting areas in a diagonal direction between the first direction and the second direction, and spaced from the plurality of first light-emitting areas in the first direction and the second direction; a sensor area surrounded by the first, second, and third light-emitting areas; a plurality of first separation portions surrounding around a half or more of an edge of each of the first, second, and third light-emitting areas; a first opening portion exposing the edge of each of the first, second, and third light-emitting areas toward at least one of the first, second, or third light-emitting areas adjacent thereto; a plurality of second separation portions surrounding around a half or more of an edge of the sensor area; and a second opening portion exposing the edge of the sensor area toward at least one of the first or third light-emitting areas adjacent thereto.

In an embodiment, a direction in which adjacent light-emitting areas of the first, second, and third light-emitting areas may be disposed and a direction in which the first opening portion may be disposed based on a center of a corresponding light-emitting area may be different from each other.

In an embodiment, a direction in which the sensor area and the second light-emitting area may be adjacent to each other and a direction in which the second opening portion may be disposed based on a center of the sensor area may be different from each other.

In an embodiment, the first opening portion may not be located on a shortest distance between adjacent light-emitting areas of the first, second, and third light-emitting areas.

In an embodiment, the second opening portion may not be located on a shortest distance between one of the second light-emitting areas and the senor area, which may be adjacent to each other.

In an embodiment, the display device may further include a spacer surrounded by the first, second, and third light-emitting areas, and having an embossed shape protruded from a pixel defining layer.

According to some embodiments of the present disclosure, a separation portion disposed between a light-emitting area and a sensor area may cut (e.g., may divide) a hole transporting layer, an electron transporting layer, and a common electrode, thereby minimizing or reducing a leakage current flowing in a fingerprint sensor even in a high-resolution structure in which the pixels and the fingerprint sensor are concentrated, and thus, a sensitivity of the fingerprint sensor may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view illustrating a display device according to some embodiments;

FIG. 2 is a cross-sectional view illustrating a display device according to some embodiments;

FIG. 3 is a plan view illustrating a display unit of a display device according to some embodiments;

FIG. 4 is a block diagram illustrating a display panel and a display driver according to some embodiments;

FIG. 5 is a plan view illustrating a display area of a display device according to some embodiments;

FIG. 6 is a circuit diagram illustrating a pixel of a display device according to some embodiments;

FIG. 7 is a cross-sectional view illustrating a pixel of a display device according to some embodiments;

FIG. 8 is a circuit diagram illustrating a fingerprint sensor of a display device according to some embodiments;

FIG. 9 is a cross-sectional view illustrating a fingerprint sensor of a display device according to some embodiments;

FIG. 10 is a cross-sectional view taken along the line I-I′ of FIG. 5;

FIG. 11 is a cross-sectional view taken along the line I-I′ of FIG. 5;

FIG. 12 is a cross-sectional view taken along the line I-I′ of FIG. 5;

FIG. 13 is a plan view illustrating a display area of a display device according to another embodiment;

FIG. 14 is a cross-sectional view taken along the line II-II′ of FIG. 13;

FIG. 15 is a cross-sectional view taken along the line II-II′ of FIG. 13; and

FIG. 16 is a cross-sectional view taken along the line II-II′ of FIG. 13.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

For example, an implanted region illustrated as a rectangle may have rounded or curved features and/or a gradient of implant concentration at its edges, rather than a binary change from an implanted to a non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device, and thus, are not intended to be limiting.

In addition, in the figures, the use of cross-hatching and/or shading is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and the like of the elements, unless otherwise specified.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

Further, as used herein, the phrases “on a plane” and “in a plan view” may refer to a view of a target portion from the top, and the phrases “on a cross-section” and “in a cross-sectional view” may refer to a view of a cross-section formed by vertically cutting a target portion from the side.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

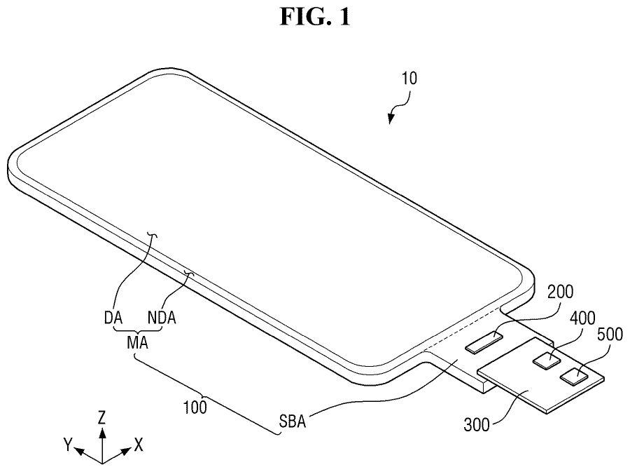

FIG. 1 is a perspective view illustrating a display device according to some embodiments.

Referring to FIG. 1, a display device 10 may be applied to a portable electronic device, such as a mobile phone, a smart phone, a tablet personal computer (PC), a mobile communication terminal, an electronic diary, an electronic book, a portable multimedia player (PMP), a navigator, and an ultra mobile PC (UMPC). For example, the display device 10 may be applied to a television, a laptop computer, a monitor, a signboard, or a display unit (e.g., a display) of an Internet of things (IoT) device. For another example, the display device 10 may be applied to a wearable device, such as a smart watch, a watch phone, an eyeglasses-type display, and a head mounted display (HMD).

The display device 10 may be formed in a planar shape, similar to that of a rectangular shape. For example, the display device 10 may have a planar shape having short sides extending in the X-axis direction, and long sides extending in the Y-axis direction. A corner where a short side extending in the X-axis direction and a long side extending in the Y-axis direction meet each other may be rounded to have a suitable curvature (e.g., a predetermined curvature), or may be formed at a right angle. The planar shape of the display device 10 may be formed to be similar to that of other suitable polygonal shapes, a circular shape, or an oval shape, without being specifically limited to the rectangular shape.

The display device 10 may include a display panel 100, a display driver 200, a circuit board 300, a touch driver 400, and a power supply unit (e.g., a power supply) 500.

The display panel 100 may include a main area MA and a sub-area SBA.

The main area MA may include a display area DA having pixels for displaying an image, and a non-display area NDA disposed near (e.g., adjacent to) the display area DA. The display area DA may emit light from a plurality of light-emitting areas or a plurality of opening areas. For example, the display panel 100 may include a pixel circuit including switching elements, a pixel defining layer defining a light-emitting area or an opening area, and a self-light emitting element.

For example, the self-light emitting element may include at least one of an organic light emitting diode including an organic light emitting layer, a quantum dot light emitting diode including a quantum dot light emitting layer, an inorganic light emitting diode including an inorganic semiconductor, or a micro light emitting diode (e.g., a micro LED), but the present disclosure is not limited thereto.

The non-display area NDA may be an outer area of the display area DA. The non-display area NDA may be defined as an edge area of the main area MA of the display panel 100. The non-display area NDA may include a gate driver for supplying gate signals to gate lines, and fan-out lines connecting the display driver 200 with the display area DA.

The sub-area SBA may be extended from one side of the main area MA. The sub-area SBA may include a flexible material capable of being subjected to bending, folding, rolling, and/or the like. For example, when the sub-area SBA is bent, the sub-area SBA may overlap with the main area MA in a thickness direction (e.g., the Z-axis direction). The sub-area SBA may include a display driver 200 and a pad portion connected to the circuit board 300. However, the present disclosure is not limited thereto, and the sub-area SBA may be omitted as needed or desired, such that the display driver 200 and the pad portion may be disposed in the non-display area NDA.

The display driver 200 may output signals and voltages for driving the display panel 100. The display driver 200 may supply data voltages to data lines. The display driver 200 may supply a power voltage to a power line, and may supply a gate control signal to the gate driver. The display driver 200 may receive a sensing signal through a read-out line. The display driver 200 may be formed of an integrated circuit (IC), and may be packaged on the display panel 100 by a chip on glass (COG) method, a chip on plastic (COP) method, or an ultrasonic bonding method. For example, the display driver 200 may be disposed in the sub-area SBA, and may overlap with the main area MA in the thickness direction (e.g., the Z-axis direction) by bending of the sub-area SBA. For another example, the display driver 200 may be packaged on the circuit board 300.

The circuit board 300 may be attached onto the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be packaged on the circuit board 300. The touch driver 400 may be electrically connected to a touch sensing unit (e.g., a touch sensor, a touch sensing layer, or a touch sensing panel) of the display panel 100. The touch driver 400 may supply a touch driving signal to a plurality of touch electrodes of the touch sensing unit, and may sense a change amount in a capacitance between the plurality of touch electrodes. For example, the touch driving signal may be a pulse signal having a suitable frequency (e.g., a predetermined frequency). The touch driver 400 may calculate an input and input coordinates based on the change amount in the capacitance between the plurality of touch electrodes. The touch driver 400 may be formed of an integrated circuit (IC).

The power supply unit 500 may be disposed on the circuit board 300 to supply the power voltage to the display driver 200 and the display panel 100. For example, the power supply unit 500 may generate a driving voltage to supply the driving voltage to a driving voltage line, and may generate a common voltage to supply the common voltage to a common electrode that is common to a plurality of light emitting elements. For example, the driving voltage may be a high potential voltage for driving the light emitting element, and the common voltage may be a low potential voltage for driving the light emitting element. The power supply unit 500 may generate an initialization voltage to supply the initialization voltage to an initialization voltage line, may generate a reference voltage to supply the reference voltage to a reference voltage line, may generate a bias voltage to supply the bias voltage to a bias voltage line, and may generate a reset voltage to supply the reset voltage to a reset voltage line.

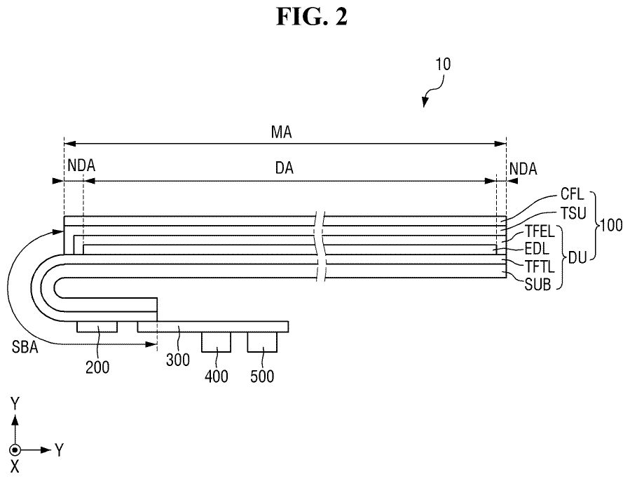

FIG. 2 is a cross-sectional view illustrating a display device according to some embodiments.

Referring to FIG. 2, the display panel 100 may include a display unit (e.g., a display or a display layer) DU, a touch sensing unit (e.g., a touch sensor, a touch sensing layer, or a touch sensing panel) TSU, and a color filter layer CFL. The display unit DU may include a substrate SUB, a transistor layer TFTL, a light emitting element layer EDL, and an encapsulation layer TFEL.

The substrate SUB may be a base substrate or a base member. The substrate SUB may be a flexible substrate capable of being subjected to bending, folding, rolling, and/or the like. For example, the substrate SUB may include a polymer resin such as polyimide (PI), but the present disclosure is not limited thereto. As another example, the substrate SUB may include a glass material or a metal material.

The transistor layer TFTL may be disposed on the substrate SUB. The transistor layer TFTL may include a plurality of thin film transistors constituting a pixel and a fingerprint sensor. The transistor layer TFTL may further include gate lines, data lines, power lines, read-out lines, gate control lines, fan-out lines for connecting the display driver 200 with the data lines, and lead lines for connecting the display driver 200 with the pad portion. Each of the transistors may include a semiconductor area, a source electrode, a drain electrode, and a gate electrode. For example, when the gate driver is formed on one side of the non-display area NDA of the display panel 100, the gate driver may include a plurality of transistors.

The transistor layer TFTL may be disposed in the display area DA, the non-display area NDA, and the sub-area SBA. The transistors, the gate lines, the data lines, the power lines, and the read-out lines of the transistor layer TFTL may be disposed in the display area DA. The gate control lines and the fan-out lines of the transistor layer TFTL may be disposed in the non-display area NDA. The lead lines of the transistor layer TFTL may be disposed in the sub-area SBA.

The light emitting element layer EDL may be disposed on the transistor layer TFTL. The light emitting element layer EDL may include a light emitting element of a pixel, a light receiving element of a fingerprint sensor, and a pixel defining layer defining the pixel and the fingerprint sensor. The light emitting element may include a pixel electrode, a light emitting layer, and a common electrode, which are sequentially stacked to emit light. The light receiving element may include a sensor electrode, a light receiving layer, and a common electrode, which are sequentially stacked to receive light. The light emitting elements and the light receiving elements of the light emitting element layer EDL may be disposed in the display area DA.

For example, the light emitting layer may be an organic light emitting layer that includes an organic material. The light emitting layer may include a hole transporting layer, an organic light emitting layer, and an electron transporting layer. When the pixel electrode receives a suitable voltage (e.g., a predetermined voltage) through the transistor of the thin transistor layer TFTL, and the common electrode receives a cathode voltage, holes may move to the organic light emitting layer through the hole transporting layer and electrons may move to the organic light emitting layer through the electron transporting layer, and the holes and the electrons may be combined with each other in the organic light emitting layer to emit light. For example, the pixel electrode may be an anode electrode, and the common electrode may be a cathode electrode, but the present disclosure is not limited thereto.

As another example, the plurality of light emitting elements may include a quantum dot light emitting diode including a quantum dot light emitting layer, an inorganic light emitting diode including an inorganic semiconductor, or a micro light emitting diode.

The light receiving element may receive light, and may convert light energy into an electric signal. When a user's finger touches (e.g., contacts) the display panel 100, the light emitted from the light emitting element may be reflected on the finger, and the light receiving element may receive the reflected light. A sensing signal of the fingerprint sensor that has received the light reflected by a ridge of the finger may be different from a sensing signal of the fingerprint sensor that has received the light reflected by a valley of the finger. A main processor may generate sensing data by distinguishing a difference between the sensing signals, and may determine whether the ridge or the valley of the finger has been touched (e.g., has been contacted) on the display panel 100, based on the sensing data. Therefore, the display device 10 may recognize a pattern of a user fingerprint based on the sensing data. For example, the light receiving element may be an organic photodiode, but the present disclosure is not limited thereto.

The encapsulation layer TFEL may cover an upper surface and sides of the light emitting element layer EDL, and may protect the light emitting element layer EDL. The encapsulation layer TFEL may include at least one inorganic layer, and at least one organic layer, which encapsulate the light emitting element layer EDL.

The touch sensing unit TSU may be disposed on the encapsulation layer TFEL. The touch sensing unit TSU may include a plurality of touch electrodes for sensing a user's touch in a capacitance manner, and touch lines connecting the plurality of touch electrodes with the touch driver 400. The plurality of touch electrodes of the touch sensing unit TSU may be disposed in a touch sensor area that overlaps with the display area DA. The touch lines of the touch sensing unit TSU may be disposed in a touch peripheral area that overlaps with the non-display area NDA. For example, the touch sensing unit TSU may sense the user's touch in a mutual capacitance manner or a self-capacitance manner.

As another example, the touch sensing unit TSU may be disposed on a separate substrate that is disposed on the display unit DU. In this case, the substrate supporting the touch sensing unit TSU may be a base member for encapsulating the display unit DU.

The color filter layer CFL may be disposed on the touch sensing unit TSU. The color filter layer CFL may include a plurality of color filters corresponding to the plurality of light-emitting areas, respectively. Each of the color filters may selectively transmit light of a desired wavelength (e.g., a particular or predetermined wavelength), and may block or absorb light of another wavelength. The color filter layer CFL may absorb a portion of light incident from the outside of the display device 10 to reduce reflective light due to external light. Therefore, the color filter layer CFL may prevent or substantially prevent a distortion of a color due to a reflection of external light from occurring.

As the color filter layer CFL is directly disposed on the touch sensing unit TSU, the display device 10 may not use or include a separate substrate for the color filter layer CFL. Therefore, a thickness of the display device 10 may be relatively reduced.

The sub-area SBA of the display panel 100 may be extended from one side of the main area MA. The sub-area SBA may include a flexible material capable of being subjected to bending, folding, rolling, and/or the like. For example, when the sub-area SBA is bent, the sub-area SBA may overlap with the main area MA in the thickness direction (e.g., the Z-axis direction). The sub-area SBA may include the display driver 200 and the pad portion electrically connected to the circuit board 300.

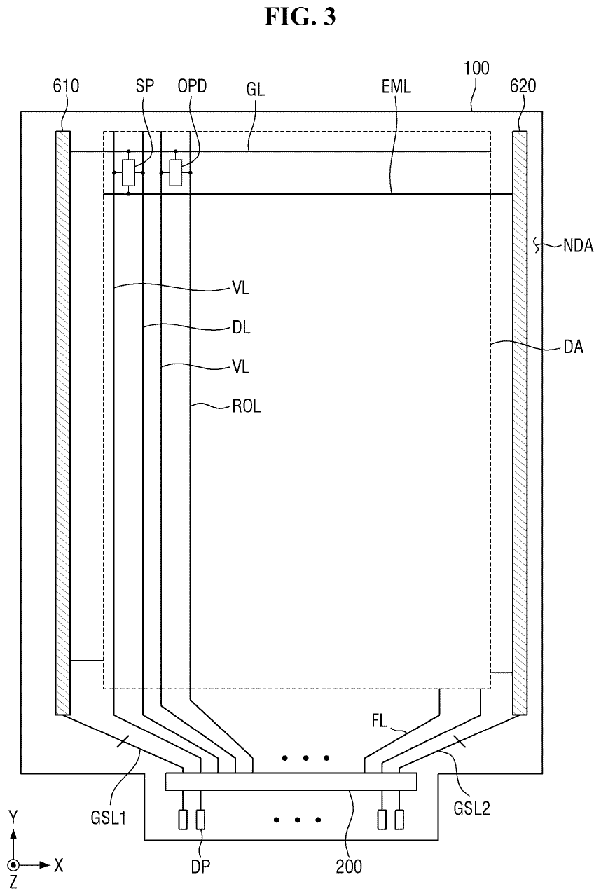

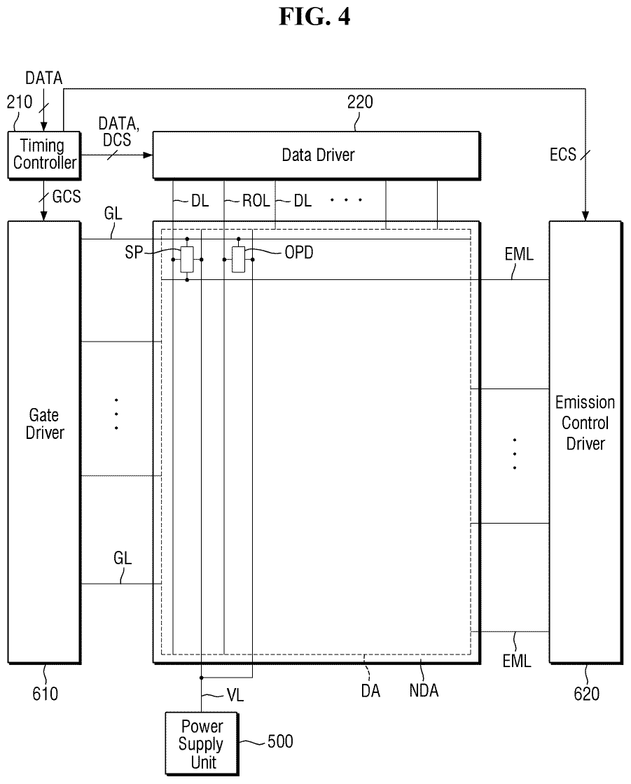

FIG. 3 is a plan view illustrating a display unit of a display device according to some embodiments, and FIG. 4 is a block diagram illustrating a display panel and a display driver according to some embodiments.

Referring to FIGS. 3 and 4, the display panel 100 may include a display area DA and a non-display area NDA. The display area DA may include a plurality of pixels SP, a plurality of fingerprint sensors OPD, power lines VL, data lines DL, a read-out line ROL, gate lines GL, and light-emitting control lines EML.

Each of the plurality of pixels SP may be connected to a corresponding gate line GL, a corresponding light-emitting control line EML, a corresponding data line DL, and a corresponding power line VL. Each of the plurality of pixels SP may include a plurality of transistors, a light emitting element, and a capacitor.

Each of the plurality of fingerprint sensors OPD may be connected to a corresponding gate line GL, a corresponding power line VL, and a corresponding read-out line ROL. Each of the plurality of fingerprint sensors OPD may include a plurality of transistors and a light receiving element.

The gate lines GL may be extended in the X-axis direction, and may be spaced apart from each other along the Y-axis direction crossing the X-axis direction. The gate lines GL may sequentially supply gate signals to the pixels SP and the fingerprint sensors OPD.

The light-emitting control lines EML may be extended in the X-axis direction, and may be spaced apart from each other along the Y-axis direction. The light-emitting control lines EML may sequentially supply light-emitting signals to the pixels SP.

The data lines DL may be extended in the Y-axis direction, and may be spaced apart from each other along the X-axis direction. The data lines DL may supply the data voltage to the pixels SP. The data voltage may determine a luminance of each of the corresponding pixels SP receiving it.

The power lines VL may be extended in the Y-axis direction, and may be spaced apart from each other along the X-axis direction. The power lines VL may supply the power voltage to the pixels SP and the fingerprint sensors OPD. In this case, the power voltage may be a driving voltage, a common voltage, an initialization voltage, a reference voltage, a bias voltage, or a reset voltage. The driving voltage may be a high potential voltage for driving the pixels SP, and the common voltage may be a low potential voltage for driving the pixel SP and the fingerprint sensor OPD.

The non-display area NDA may surround (e.g., around a periphery of) the display area DA. The non-display area NDA may include a gate driver 610, a light-emitting control driver 620, fan-out lines FL, a first gate control line GSL1, and a second gate control line GSL2.

The fan-out lines FL may be extended from the display driver 200 to the display area DA. The fan-out lines FL may supply the data voltage received from the display driver 200 to the data line DL, may supply the power voltage received from the display driver 200 to the power line VL, and may supply the sensing signal received from the read-out line ROL to the display driver 200. Therefore, the display driver 200 may drive the pixel SP and the fingerprint sensor OPD.

The first gate control line GSL1 may be extended from the display driver 200 to the gate driver 610. The first gate control line GSL1 may supply a gate control signal GCS received from the display driver 200 to the gate driver 610.

The second gate control line GSL2 may be extended from the display driver 200 to the light-emitting control driver 620. The second gate control line GSL2 may supply a light-emitting control signal ECS received from the display driver 200 to the light-emitting control driver 620.

The sub-area SBA may be extended from one side of the non-display area NDA. The sub-area SBA may include the display driver 200 and a pad portion DP. The pad portion DP may be disposed to be more adjacent to an edge of one side of the sub-area SBA than (e.g., when compared to) the display driver 200. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS based on the timing signals, and may supply the digital video data DATA and the data control signal DCS to the data driver 220 to control an operation timing of the data driver 220. The timing controller 210 may generate the gate control signal GCS to supply the gate control signal GCS to the gate driver 610, and may control an operation timing of the gate driver 610. The timing controller 210 may generate the light-emitting control signal ECS to supply the light-emitting control signal ECS to the light-emitting control driver 620, and may control an operation timing of the light-emitting control driver 620.

The data driver 220 may convert the digital video data DATA into analog data voltages, and supply the analog data voltages to the data lines DL through the fan-out lines FL. The gate signals of the gate driver 610 may select pixels SP to which a data voltage is supplied, and the selected pixels SP may receive the data voltage through the data lines DL. The data driver 220 may supply the sensing signal received through the read-out line ROL to the main processor.

The power supply unit 500 may be disposed on the circuit board 300 to supply the power voltage to the display driver 200 and the display panel 100. The power supply unit 500 may generate the power voltage to supply the power voltage to the power line VL, and may generate the common voltage to supply the common voltage to the common electrode common to the pixels SP and the fingerprint sensors OPD. The power supply unit 500 may generate the initialization voltage to supply the initialization voltage to the initialization voltage line, may generate the reference voltage to supply the reference voltage to the reference voltage line, may generate the bias voltage to supply the bias voltage to the bias voltage line, and may generate the reset voltage to supply the reset voltage to the reset voltage line.

The gate driver 610 may be disposed outside one side of the display area DA (e.g., at one side of the non-display area NDA), and the light-emitting control driver 620 may be disposed outside another side (e.g., an opposite side) of the display area DA (e.g., at the opposite side of the non-display area NDA), but the present disclosure is not limited thereto. As another example, the gate driver 610 and the light-emitting control driver 620 may be disposed at any one of one side and the other side of the non-display area NDA.

The gate driver 610 may include a plurality of transistors for generating gate signals based on the gate control signal GCS. The light-emitting control driver 620 may include a plurality of transistors for generating light-emitting signals based on the light-emitting control signal ECS. For example, the transistors of the gate driver 610 and the transistors of the light-emitting control driver 620 may be formed at (e.g., in or on) the same layer as that of the transistors of the respective pixels SP. The gate driver 610 may supply the gate signals to the gate lines GL, and the light-emitting control driver 620 may supply the light-emitting signals to the light-emitting control lines EML.

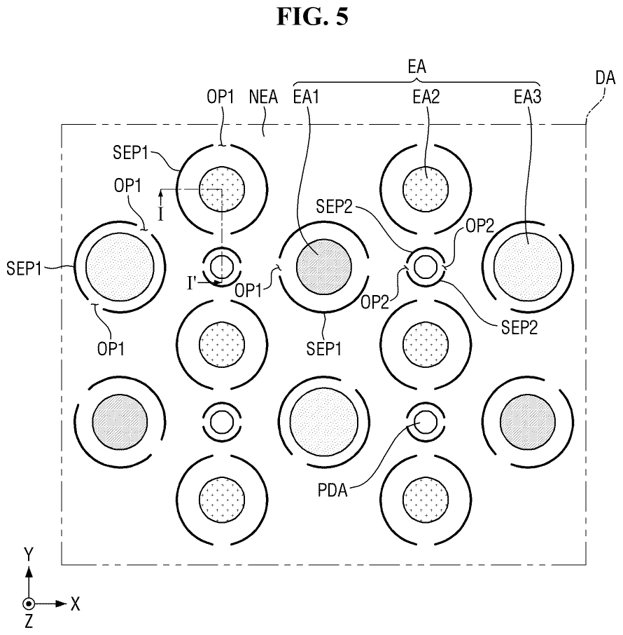

FIG. 5 is a plan view illustrating a display area of a display device according to some embodiments.

Referring to FIG. 5, the display area DA may include light-emitting areas EA and a non-light-emitting area NEA. The light-emitting areas EA may emit light of the light emitting elements, and the light emitting elements may not be disposed in the non-light-emitting area NEA. The non-light-emitting area NEA may include sensor areas PDA spaced apart from each other with at least one light-emitting area EA interposed therebetween. The light-emitting areas EA may include first to third light-emitting areas EA1, EA2 and EA3. For example, the first light-emitting area EA1 may emit light of a first color (e.g., red light), the second light-emitting area EA2 may emit light of a second color (e.g. green light), and the third light-emitting area EA3 may emit light of a third color (e.g., blue light), but the present disclosure is not limited thereto.

One unit pixel may include one first light-emitting area EA1, two second light-emitting areas EA2 and one third light-emitting area EA3 to represent a white gray scale, but the configuration of the unit pixel is not limited thereto. The white gray scale may be represented by a combination of the light emitted from one first light-emitting area EA1, the two second light-emitting areas EA2, and the one third light-emitting area EA3.

Sizes of the first to third light-emitting areas EA1, EA2 and EA3 may be different from one another. For example, the size of the third light-emitting area EA3 may be greater than that of the first light-emitting area EA1, and the size of the first light-emitting area EA1 may be greater than that of the second light-emitting area EA2. As another example, the sizes of the first to third light-emitting areas EA1, EA2 and EA3 may be the same or substantially the same as one another.

A first separation portion SEP1 may surround (e.g., around a periphery of) a portion of each of the first to third light-emitting areas EA1, EA2 and EA3. For example, a plurality of first separation portions SEP1 may surround (e.g., around a periphery of) a half or more of an edge of the first light-emitting area EA1, and the other portion of the edge of the first light-emitting area EA1 may be exposed toward its peripheral light-emitting area EA by first opening portions OP1. The first opening portion OP1 may be disposed between the first separation portions SEP1 adjacent to each other. A direction in which the light-emitting areas EA are adjacent to each other may be different from a direction in which the first opening portion OP1 is disposed. The first opening portion OP1 may not be disposed on the shortest distance between the adjacent light-emitting areas EA. For example, the first opening portion OP1 of each of the second light-emitting areas EA2 adjacent to each other in the X-axis direction may be disposed in the Y-axis direction with respect to a center of the second light-emitting area EA2. The first opening portion OP1 of each of the first and third light-emitting areas EA1 and EA3 adjacent to each other in the Y-axis direction may be disposed in the X-axis direction with respect to a center of each of the first and third light-emitting areas EA1 and EA3, or may be disposed in a diagonal direction between the X-axis and Y-axis directions. At least one first separation portion SEP1 may be disposed on the shortest distance between the adjacent light-emitting areas EA. At least one first separation portion SEP1 may be disposed on a virtual line connecting centers of the adjacent light-emitting areas EA to each other.

The first separation portion SEP1 may have an embossed shape protruded from the pixel defining layer, or an engraved shape recessed from an upper surface of the pixel defining layer. The embossed shape of the first separation portion SEP1 may have a tapered angle structure or a reverse tapered angle structure. The first separation portion SEP1 may cut the hole transporting layer, the electron transporting layer, and the common electrode on the shortest distance between the adjacent light-emitting areas EA. The hole transporting layer, the electron transporting layer, and the common electrode may not be cut by the first opening portion OP1. The first separation portion SEP1 may cut the hole transporting layer, the electron transporting layer and the common electrode between the adjacent light-emitting areas EA, thereby minimizing or reducing a leakage current flowing in the pixel SP even in a high-resolution structure in which the pixels SP and the fingerprint sensor OPD are concentrated, and thus, a sensitivity of the fingerprint sensor OPD may be improved.

The sensor area PDA may be surrounded (e.g., around a periphery thereof) by the first to third light-emitting areas EA1, EA2 and EA3. The sensor area PDA may be adjacent to the first or third light-emitting area EA1 or EA3 in the X-axis direction, and may be adjacent to the second light-emitting area EA2 in the Y-axis direction. The sensor areas PDA may be spaced apart from each other with at least one light-emitting area EA interposed therebetween. The sensor area PDA may receive light emitted from the second light-emitting area EA2 and reflected by the fingerprint.

A second separation portion SEP2 may surround (e.g., around a periphery of) a portion of the sensor area PDA. For example, a plurality of second separation portions SEP2 may surround (e.g., around a periphery of) a half or more of an edge of the sensor area PDA, and the other portion of the edge of the sensor area PDA may be exposed toward its peripheral first and third light-emitting areas EA1 and EA3 by second opening portions OP2. The second opening portion OP2 may be disposed between the second separation portions SEP2 adjacent to each other. A direction in which the sensor area PDA and the second light-emitting areas EA2 are adjacent to each other may be different from a direction in which the second opening portion OP2 is disposed. The second opening portion OP2 may not be disposed on the shortest distance between the sensor area PDA and the second light-emitting area EA2, which are adjacent to each other. For example, when the sensor area PDA and the second light-emitting area EA2 are adjacent to each other in the Y-axis direction, the second opening portion OP1 may be disposed in the X-axis direction with respect to a center of the sensor area PDA. At least one second separation portion SEP2 may be disposed on the shortest distance between the sensor area PDA and the second light-emitting area EA2, which are adjacent to each other. At least one second separation portion SEP2 may be disposed on a virtual line connecting centers of the sensor area PDA and the second light-emitting area EA2, which are adjacent to each other, to each other.

A distance between the second separation portion SEP2 and the sensor area PDA may be shorter than a distance between the first separation portion SEP1 and the light-emitting area EA. Therefore, the second separation portion SEP2 may have an embossed shape protruded from the pixel defining layer. The embossed shape of the second separation portion SEP2 may have a tapered angle structure or a reverse tapered angle structure. The second separation portion SEP2 may cut the hole transporting layer, the electron transporting layer, and the common electrode on the shortest distance between the sensor area PDA and the second light-emitting area EA2, which are adjacent to each other. The hole transporting layer, the electron transporting layer, and the common electrode may not be cut by the second opening portion OP2. The second separation portion SEP2 may cut the hole transporting layer, the electron transporting layer, and the common electrode between the sensor area PDA and the second light-emitting area EA2, which are adjacent to each other, thereby minimizing or reducing a leakage current flowing in the fingerprint sensor OPD even in a high-resolution structure in which the pixels SP and the fingerprint sensor OPD are concentrated, and improving sensitivity of the fingerprint sensor OPD.

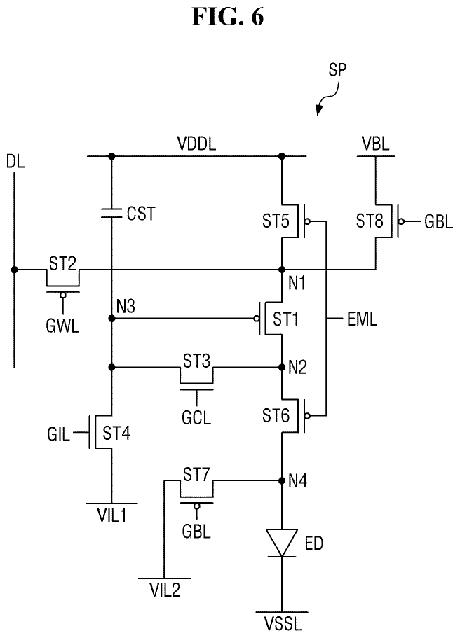

FIG. 6 is a circuit diagram illustrating a pixel of a display device according to some embodiments.

Referring to FIG. 6, the pixel SP may be connected to a first gate line GWL, a second gate line GCL, a third gate line GIL, a fourth gate line GBL, a light-emitting control line EML, a data line DL, a driving voltage line VDDL, a first initialization voltage line VIL1, a second initialization voltage line VIL2, a bias voltage line VBL, and a low potential line VSSL.

The pixel SP may include a light emitting element ED, and a pixel circuit for driving the light emitting element ED. The pixel circuit may include first to eighth transistors ST1, ST2, ST3, ST4, ST5, ST6, ST7 and ST8, and a capacitor CST.

The first transistor ST1 may control a driving current supplied to the light emitting element ED. The first transistor ST1 may include a gate electrode, a first electrode and a second electrode. The gate electrode of the first transistor ST1 may be connected to a third node N3, the first electrode of the first transistor ST1 may be connected to a first node N1, and the second electrode of the first transistor ST1 may be connected to a second node N2. For example, the first electrode of the first transistor ST1 may be a source electrode, and the second electrode thereof may be a drain electrode, but the present disclosure is not limited thereto.

The first transistor ST1 may control a source-drain current (hereinafter, referred to as “driving current”) in accordance with the data voltage applied to the gate electrode. The driving current flowing through a channel of the first transistor ST1 may be proportional to a square of a difference between a voltage Vsg between the source electrode and the gate electrode of the first transistor ST1 and a threshold voltage Vth (e.g., Isd=k×(Vsg−Vth)²). In this case, k denotes a proportional coefficient determined by a structure and physical characteristics of the first transistor ST1, Vsg denotes a source-gate voltage of the first transistor ST1, and Vth denotes the threshold voltage of the first transistor ST1.

The light emitting element ED may emit light by receiving the driving current Isd. The light emitting amount or the luminance of the light emitting element ED may be proportional to a magnitude of the driving current Isd. The light emitting element ED may include a first electrode, a second electrode, and a light emitting layer disposed between the first electrode and the second electrode. The first electrode of the light emitting element ED may be connected to a fourth node N4. The first electrode of the light emitting element ED may be connected to a second electrode of the sixth transistor ST6 and a first electrode of the seventh transistor ST7 through the fourth node N4. The second electrode of the light emitting element ED may be electrically connected to the low potential line VSSL. The second electrode of the light emitting element ED may receive a low potential voltage. For example, the first electrode of the light emitting element ED may be an anode electrode or a pixel electrode, and the second electrode thereof may be a cathode electrode or a common electrode, but the present disclosure is not limited thereto.

The second transistor ST2 may be turned on by a first gate signal of the first gate line GWL to electrically connect the data line DL with the first node N1 that is the first electrode of the first transistor ST1. The second transistor ST2 may be turned on based on the first gate signal to supply a data voltage to the first node N1. A gate electrode of the second transistor ST2 may be connected to the first gate line GWL, a first electrode of the second transistor ST2 may be connected to the data line DL, and a second electrode of the second transistor ST2 may be connected to the first node N1. The second electrode of the second transistor ST2 may be connected to the first electrode of the first transistor ST1, a second electrode of the fifth transistor ST5, and a second electrode of the eighth transistor ST8 through the first node N1. For example, the first electrode of the second transistor ST2 may be a source electrode, and the second electrode of the second transistor ST2 may be a drain electrode, but the present disclosure is not limited thereto.

The third transistor ST3 may be turned on by a second gate signal of the second gate line GCL to electrically connect the second node N2, which is the second electrode of the first transistor ST1, with the third node N3 that is the gate electrode of the first transistor ST1. A gate electrode of the third transistor ST3 may be connected to the second gate line GCL, a first electrode of the third transistor ST3 may be connected to the second node N2, and a second electrode of the third transistor ST3 may be connected to the third node N3. The first electrode of the third transistor ST3 may be connected to the second electrode of the first transistor ST1 and a first electrode of the sixth transistor ST6 through the second node N2. The second electrode of the third transistor ST3 may be connected to the gate electrode of the first transistor ST1, a first electrode of the fourth transistor ST4, and a first capacitor electrode of the capacitor CST through the third node N3. For example, the first electrode of the third transistor ST3 may be a drain electrode, and the second electrode of the third transistor ST3 may be a source electrode, but the present disclosure is not limited thereto.

The fourth transistor ST4 may be turned on by a third gate signal of the third gate line GIL to electrically connect the third node N3, which is the gate electrode of the first transistor ST1, with the first initialization voltage line VIL1. The fourth transistor ST4 may be turned on based on the third gate signal to discharge the gate electrode of the first transistor ST1 with a first initialization voltage. A gate electrode of the fourth transistor ST4 may be connected to the third gate line GIL, the first electrode of the fourth transistor ST4 may be connected to the third node N3, and a second electrode of the fourth transistor ST4 may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. For example, the first electrode of the fourth transistor ST4 may be a drain electrode, and the second electrode of the fourth transistor ST4 may be a source electrode, but the present disclosure is not limited thereto.

The fifth transistor ST5 may be turned on by the light-emitting signal of the light-emitting control line EML to electrically connect the driving voltage line VDDL with the first node N1 that is the first electrode of the first transistor ST1. A gate electrode of the fifth transistor ST5 may be connected to the light-emitting control line EML, a first electrode of the fifth transistor ST5 may be connected to the driving voltage line VDDL, and the second electrode of the fifth transistor ST5 may be connected to the first node N1. The second electrode of the fifth transistor ST5 may be electrically connected to the first electrode of the first transistor ST1, the second electrode of the second transistor ST2, and the second electrode of the eighth transistor ST8 through the first node N1. For example, the first electrode of the fifth transistor ST5 may be a source electrode, and the second electrode of the fifth transistor ST5 may be a drain electrode, but the present disclosure is not limited thereto.

The sixth transistor ST6 may be turned on by the light-emitting signal of the light-emitting control line EML to electrically connect the second node N2, which is the second electrode of the first transistor ST1, with the fourth node N4 that is the first electrode of the light emitting element ED. A gate electrode of the sixth transistor ST6 may be connected to the light-emitting control line EML, the first electrode of the sixth transistor ST6 may be connected to the second node N2, and the second electrode of the sixth transistor ST6 may be connected to the fourth node N4. The first electrode of the sixth transistor ST6 may be connected to the second electrode of the first transistor ST1 and the first electrode of the third transistor ST3. The second electrode of the sixth transistor ST6 may be connected to the first electrode of the light emitting element ED and the first electrode of the seventh transistor ST7 through the fourth node N4. For example, the first electrode of the sixth transistor ST6 may be a source electrode, and the second electrode of the sixth transistor ST6 may be a drain electrode, but the present disclosure is not limited thereto.

When the fifth transistor ST5, the first transistor ST1, and the sixth transistor ST6 are all turned on, the driving current may be supplied to the light emitting element ED.

The seventh transistor ST7 may be turned on by a fourth gate signal of the fourth gate line GBL to electrically connect the second initialization voltage line VIL2 with the fourth node N4 that is the first electrode of the light emitting element ED. The seventh transistor ST7 may be turned on based on the fourth gate signal to discharge the first electrode of the light emitting element ED with a second initialization voltage. A gate electrode of the seventh transistor ST7 may be connected to the fourth gate line GBL, the first electrode of the seventh transistor ST7 may be connected to the fourth node N4, and a second electrode of the seventh transistor ST7 may be connected to the second initialization voltage line VIL2. The first electrode of the seventh transistor ST7 may be connected to the first electrode of the light emitting element ED and the second electrode of the sixth transistor ST6 through the fourth node N4. For example, the first electrode of the seventh transistor ST7 may be a source electrode, and the second electrode of the seventh transistor ST7 may be a drain electrode, but the present disclosure is not limited thereto.

The eighth transistor ST8 may be turned on by the fourth gate signal of the fourth gate line GBL to electrically connect the bias voltage line VBL to the first node N1 that is the first electrode of the first transistor ST1. A gate electrode of the eighth transistor ST8 may be connected to the fourth gate line GBL, a first electrode of the eighth transistor ST8 may be connected to the bias voltage line VBL, and the second electrode of the eighth transistor ST8 may be connected to the first node N1. The second electrode of the eighth transistor ST8 may be electrically connected to the first electrode of the first transistor ST1, the second electrode of the second transistor ST2, and the second electrode of the fifth transistor ST5 through the first node N1. For example, the first electrode of the eighth transistor ST8 may be a source electrode, and the second electrode of the eighth transistor ST8 may be a drain electrode, but the present disclosure is not limited thereto. In some embodiments, the eighth transistor ST8 may be omitted as needed or desired.

Each of the first transistor ST1, the second transistor ST2, the fifth transistor ST5, the sixth transistor ST6, the seventh transistor ST7, and the eighth transistor ST8 may include a silicon-based semiconductor area. For example, each of the first transistor ST1, the second transistor ST2, the fifth transistor ST5, the sixth transistor ST6, the seventh transistor ST7, and the eighth transistor ST8 may include a semiconductor area including (e.g., made of) a low temperature polycrystalline silicon (LTPS). The semiconductor area including (e.g., made of) the low temperature polycrystalline silicon may have high electron mobility and excellent turn-on characteristics. Therefore, the display device 10 may include the first transistor ST1, the second transistor ST2, the fifth transistor ST5, the sixth transistor ST6, the seventh transistor ST7, and the eighth transistor ST8, which have excellent turn-on characteristics, thereby more stably and efficiently driving the plurality of pixels SP.

Each of the first transistor ST1, the second transistor ST2, the fifth transistor ST5, the sixth transistor ST6, the seventh transistor ST7, and the eighth transistor ST8 may correspond to a p-type transistor. For example, each of the first transistor ST1, the second transistor ST2, the fifth transistor ST5, the sixth transistor ST6, the seventh transistor ST7, and the eighth transistor ST8 may output a current flowing into the first electrode thereof to the second electrode thereof based on a gate low voltage applied to the gate electrode thereof.

Each of the third transistor ST3 and the fourth transistor ST4 may include an oxide-based semiconductor area. For example, each of the third transistor ST3 and the fourth transistor ST4 may have a coplanar structure in which a gate electrode thereof is disposed on the oxide-based semiconductor area. The transistor having the coplanar structure has excellent leakage current characteristics and enables low frequency driving, thereby reducing a power consumption. Therefore, the display device 10 may include the third transistor ST3 and the fourth transistor ST4, which have excellent leakage current characteristics, thereby preventing or substantially preventing a leakage current from flowing into the pixel, and more stably maintaining a voltage inside the pixel.

Each of the third transistor ST3 and the fourth transistor ST4 may correspond to an n-type transistor. For example, each of the third transistor ST3 and the fourth transistor ST4 may output a current flowing into the first electrode thereof to the second electrode thereof based on a gate high voltage applied to the gate electrode thereof.

The capacitor CST may be connected between the third node N3, which is the gate electrode of the first transistor ST1, and the driving voltage line VDDL. For example, the first capacitor electrode of the capacitor CST may be connected to the third node N3, and a second capacitor electrode of the capacitor CST may be connected to the driving voltage line VDDL, so that a potential difference between the driving voltage line VDDL and the gate electrode of the first transistor ST1 may be maintained or substantially maintained.

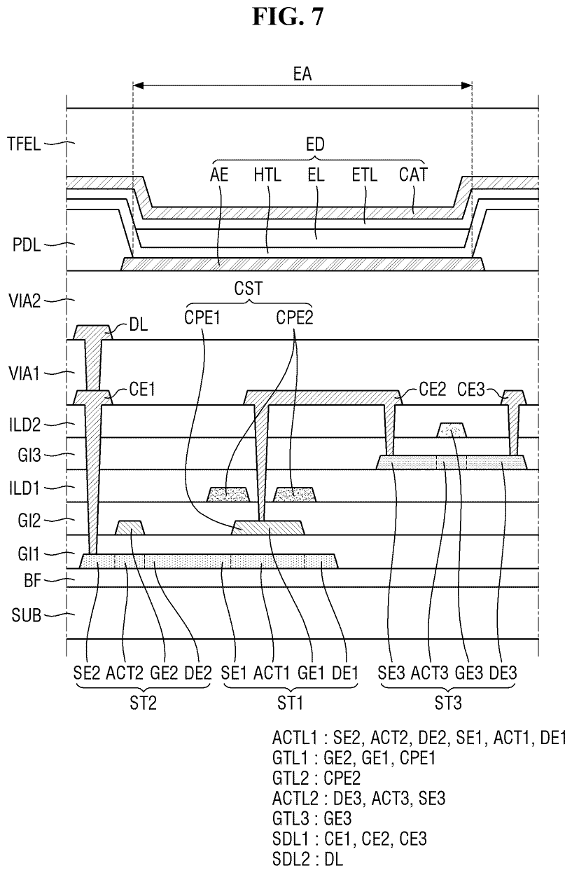

FIG. 7 is a cross-sectional view illustrating a pixel of a display device according to some embodiments.

Referring to FIG. 7, the display panel 100 may include a substrate SUB, a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, a second via layer VIA2, a pixel defining layer PDL, a light emitting element ED, and an encapsulation layer TFEL.

The substrate SUB may be a base substrate or a base member. The substrate SUB may be a flexible substrate capable of being subjected to bending, folding, rolling, or the like. For example, the substrate SUB may include a polymer resin such as polyimide (PI), but the present disclosure is not limited thereto. As another example, the substrate SUB may include a glass material or a metal material.

The buffer layer BF may be disposed on the substrate SUB. For example, the buffer layer BF may include an inorganic layer capable of preventing or substantially preventing a permeation of the air or moisture from occurring. For example, the buffer layer BF may include a plurality of inorganic layers that are alternately stacked.

The first active layer ACTL1 may be disposed on the buffer layer BF. The first active layer ACTL1 may include a silicon-based material. For example, the first active layer ACTL1 may include (e.g., may be made of) a low temperature polycrystalline silicon (LTPS). The first active layer ACTL1 may include a semiconductor area ACT1, a first electrode SE1, and a second electrode DE1 of the first transistor ST1, and a semiconductor area ACT2, a first electrode SE2, and a second electrode DE2 of the second transistor ST2.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include a gate electrode GE1 of the first transistor ST1, a gate electrode GE2 of the second transistor ST2, and a first capacitor electrode CPE1. The gate electrode GE1 of the first transistor ST1 may be a portion of the first capacitor electrode CPE1, and the gate electrode GE2 of the second transistor ST2 may be a portion of the first gate line GWL.

The second gate insulating layer GI2 may be disposed on the first gate layer GTL1. The second gate insulating layer GI2 may insulate the first gate layer GTL1 from the second gate layer GTL2.

The second gate layer GTL2 may be disposed on the second gate insulating layer GI2. The second gate layer GTL2 may include a second capacitor electrode CPE2. The second capacitor electrode CPE2 may overlap with the first capacitor electrode CPE1.

The first interlayer insulating layer ILD1 may be disposed on the second gate layer GTL2. The first interlayer insulating layer ILD1 may insulate the second gate layer GTL2 from the second active layer ACTL2.

The second active layer ACTL2 may be disposed on the first interlayer insulating layer ILD1. The second active layer ACTL2 may include an oxide-based material. The second active layer ACTL2 may include a semiconductor area ACT3, a first electrode DE3 of the third transistor ST3, and a second electrode SE3 of the third transistor ST3.

The third gate insulating layer GI3 may be disposed on the second active layer ACTL2. The third gate insulating layer GI3 may insulate the second active layer ACTL2 from the third gate layer GTL3.

The third gate layer GTL3 may be disposed on the third gate insulating layer GI3. The third gate layer GTL3 may include a gate electrode GE3 of the third transistor ST3. The gate electrode GE3 of the third transistor ST3 may be a portion of the second gate line GCL.

The second interlayer insulating layer ILD2 may be disposed on the third gate layer GTL3. The second interlayer insulating layer ILD2 may insulate the third gate layer GTL3 from the first source metal layer SDL1.

The first source metal layer SDL1 may be disposed on the second interlayer insulating layer ILD2. The first source metal layer SDL1 may include first to third connection electrodes CE1, CE2 and CE3. The first connection electrode CE1 may electrically connect the data line DL with the first electrode SE2 of the second transistor ST2. The second connection electrode CE2 may electrically connect the first capacitor electrode CPE1 with the second electrode SE3 of the third transistor ST3. The third connection electrode CE3 may electrically connect the first electrode DE3 of the third transistor ST3 with the second electrode DE1 of the first transistor ST1.

The first via layer VIA1 may be disposed on the first source metal layer SDL1. The first via layer VIA1 may insulate the first source metal layer SDL1 from the second source metal layer SDL2. An upper surface of the first via layer VIA1 may be flat or substantially flat. The first via layer VIA1 may include an organic insulating material such as polyimide (PI).

The second source metal layer SDL2 may be disposed on the first via layer VIA1. The second source metal layer SDL2 may include a data line DL.

The second via layer VIA2 may be disposed on the second source metal layer SDL2. The second via layer VIA2 may insulate the second source metal layer SDL2 from the pixel electrode AE. An upper surface of the second via layer VIA2 may be flat or substantially flat. The second via layer VIA2 may include an organic insulating material such as polyimide (PI).

The pixel defining layer PDL may be disposed on the second via layer VIA2. The pixel defining layer PDL may define a plurality of light-emitting areas EA. The pixel defining layer PDL may include an organic insulating material such as polyimide (PI).

The light emitting element ED may include a pixel electrode AE, a hole transporting layer HTL, a light emitting layer EL, an electron transporting layer ETL, and a common electrode CAT. The pixel electrode AE may be disposed on the second via layer VIA2. The pixel electrode AE may overlap with one of the plurality of light-emitting areas EA defined by the pixel defining layer PDL. The pixel electrode AE may receive a driving current from the pixel circuit of the pixel SP.

The hole transporting layer HTL may be disposed on the pixel electrode AE in the light-emitting area EA, and on the pixel defining layer PDL in the non-light-emitting area NEA. The hole transporting layer HTL may not be divided for each pixel SP, and may be implemented as a common layer of the entire pixel SP and the fingerprint sensor OPD.

The light emitting layer EL may be disposed on the hole transporting layer HTL in the light-emitting area EA. For example, the light emitting layer EL may be an organic light emitting layer including (e.g., made of) an organic material, but the present disclosure is not limited thereto.

The electron transporting layer ETL may be disposed on the light emitting layer EL in the light-emitting area EA, and may be disposed on the hole transporting layer HTL in the non-light-emitting area NEA. The electron transporting layer ETL may not be divided for each pixel SP, and may be implemented as a common layer of the entire pixel SP and the fingerprint sensor OPD.

The common electrode CAT may be disposed on the electron transporting layer ETL. For example, the common electrode CAT may not be divided for each of the plurality of pixels SP, and may be implemented in the form of an electrode common to the entire pixel SP and the fingerprint sensor OPD. The common electrode CAT may be a transparent electrode, and may transmit light. The common electrode CAT may be electrically connected to the low potential line VSSL, and may receive a low potential voltage, a common voltage, or a cathode voltage.

In the case that the light emitting layer EL corresponds to the organic light emitting layer, when the pixel circuit of the pixel SP applies a suitable voltage (e.g., a predetermined voltage) to the pixel electrode AE, and the common electrode CAT receives the common voltage or the cathode voltage, holes and electrons may move to the light emitting layer EL through the hole transporting layer HTL and the electron transporting layer ETL, respectively, and may be combined with each other in the light emitting layer EL to emit light.

The encapsulation layer TFEL may be disposed on the common electrode CAT to cover the plurality of light emitting elements ED. The encapsulation layer TFEL may include at least one inorganic layer to prevent or substantially prevent oxygen or moisture from being permeated into the plurality of light emitting elements ED. The encapsulation layer TFEL may include at least one organic layer to protect the plurality of light emitting elements ED from particles, such as dust.

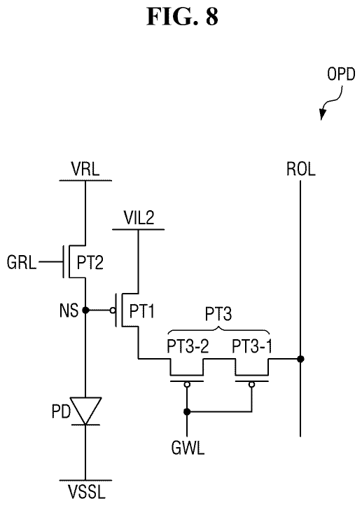

FIG. 8 is a circuit diagram illustrating a fingerprint sensor of a display device according to some embodiments.

Referring to FIG. 8, the fingerprint sensor OPD may be connected to the first gate line GWL, a reset signal line GRL, a reset voltage line VRL, the second initialization voltage line VIL2, the low potential line VSSL, and the read-out line ROL.

The fingerprint sensor OPD may include a light receiving element PD, and a fingerprint sensor circuit for driving the light receiving element PD. The fingerprint sensor circuit may include first to third sensor transistors PT1, PT2 and PT3.

The first sensor transistor PT1 may include a gate electrode, a first electrode, and a second electrode. The gate electrode of the first sensor transistor PT1 may be connected to a sensor node NS, the first electrode of the first sensor transistor PT1 may be connected to the third sensor transistor PT3, and the second electrode of the first sensor transistor PT1 may be connected to the second initialization voltage line VIL2. The first sensor transistor PT1 may control a source-drain current (hereinafter, referred to as a “sensing current”) based on a voltage of the sensor node NS, which is a first electrode of the light receiving element PD. The sensing current flowing through a channel of the first sensor transistor PT1 may be proportional to a square of a difference between a voltage Vsg between a source electrode and a gate electrode of the first sensor transistor PT1 and a threshold voltage Vth (e.g., Isd=k′×(Vsg−Vth)²). In this case, k′ denotes a proportional coefficient determined by a structure and physical characteristics of the first sensor transistor PT1, Vsg denotes a source-gate voltage of the first sensor transistor PT1, and Vth denotes the threshold voltage of the first sensor transistor PT1. The first electrode of the first sensor transistor PT1 may be a source electrode, and the second electrode of the first sensor transistor PT1 may be a drain electrode, but the present disclosure is not limited thereto.

The second sensor transistor PT2 may be turned on by a reset signal of the reset signal line GRL to discharge the voltage of the sensor node NS with the reset voltage. A gate electrode of the second sensor transistor PT2 may be connected to the reset signal line GRL, a first electrode of the second sensor transistor PT2 may be connected to the sensor node NS, and a second electrode of the second sensor transistor PT2 may be connected to the reset voltage line VRL. The first electrode of the second sensor transistor PT2 may be connected to the first electrode of the light receiving element PD and the gate electrode of the first sensor transistor PT1 through the sensor node NS. The first electrode of the second sensor transistor PT2 may be a drain electrode, and the second electrode of the second sensor transistor PT2 may be a source electrode, but the present disclosure is not limited thereto.

The third sensor transistor PT3 may be turned on by the first gate signal of the first gate line GWL to electrically connect the first electrode of the first sensor transistor PT1 with the read-out line ROL. The third sensor transistor PT3 may include a (3-1)th sensor transistor PT3-1 and a (3-2)th sensor transistor PT3-2, which are connected in series. The (3-1)th sensor transistor PT3-1 and the (3-2)th sensor transistor PT3-2 may be connected in series between the first electrode of the first sensor transistor PT1 and the read-out line ROL. A gate electrode of the (3-1)th sensor transistor PT3-1 and a gate electrode of the (3-2)th sensor transistor PT3-2 may be integrally formed with each other (e.g., may be integral with each other) to be electrically connected to the first gate line GWL. A first electrode of the (3-1)th sensor transistor PT3-1 may be connected to the read-out line ROL, and a second electrode of the (3-2)th sensor transistor PT3-2 may be connected to the first electrode of the first sensor transistor PT1. A second electrode of the (3-1)th sensor transistor PT3-1 and a first electrode of the (3-2)th sensor transistor PT3-2 may be integrally formed (e.g., may be integral with) each other. The first electrode of each of the (3-1)th sensor transistor PT3-1 and the (3-2)th sensor transistor PT3-2 may be a source electrode, and the second electrode thereof may be a drain electrode, but the present disclosure is not limited thereto.

The light receiving element PD may recognize a pattern of a user fingerprint based on light reflected from a user's finger. The first electrode of the light receiving element PD may be connected to the sensor node NS that is the gate electrode of the first sensor transistor PT1, and the second electrode of the light receiving element PD may be connected to the low potential line VSSL. The second electrode of the light receiving element PD may receive a low potential voltage from the low potential line VSSL. For example, the first electrode of the light receiving element PD may be a sensor electrode, and the second electrode of the light emitting element PD may be a common electrode, but the present disclosure is not limited thereto.

When the user's finger touches the display panel 100, the light receiving element PD may receive light reflected by the ridge or valley of the finger. The light output from the light emitting element ED may be reflected by the ridge or valley of the finger, and the reflected light may reach the light receiving element PD. The light receiving element PD may convert energy of the light into an electric signal (e.g., a current or a voltage) formed between the first electrode and the second electrode thereof, and the converted electric signal may flow from the low potential line VSSL to the sensor node NS as a reverse bias current. For example, when the light receiving element PD receives light, and thus, an electric field is formed between the first electrode and the second electrode of the light receiving element PD, the current may flow to the light receiving element PD in proportion to the quantity of light, and thus, the voltage of the sensor node NS may be increased. Therefore, when the light receiving element PD receives the light, the voltage of the sensor node NS may be increased, and the magnitude of the sensing current (e.g., the source-drain current) of the first sensor transistor PT1 may be reduced. The sensing current of the first sensor transistor PT1 may be applied to the display driver 200 as a sensing signal through the third sensor transistor PT3 and the read-out line ROL.

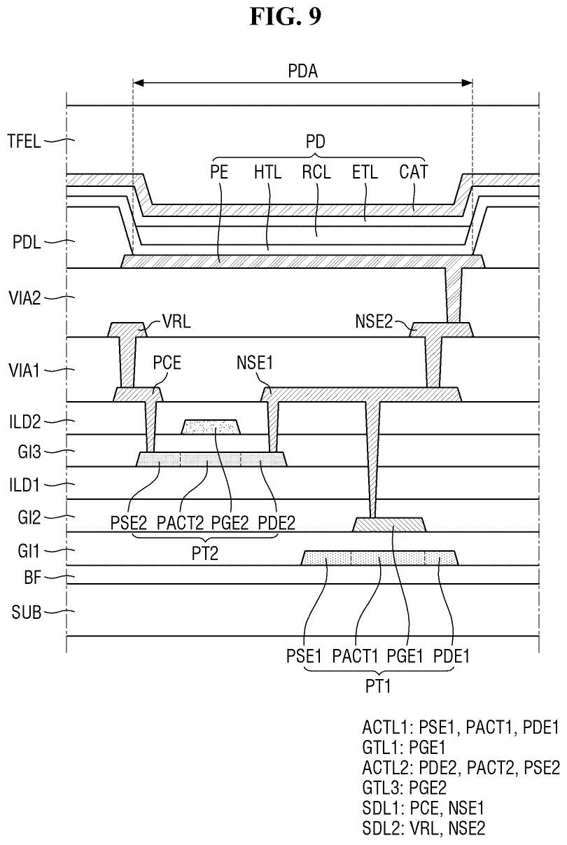

FIG. 9 is a layout view illustrating a fingerprint sensor of a display device according to some embodiments. Hereinafter, the same or substantially the same elements as those described above will be briefly described, or redundant description thereof may not be repeated.

Referring to FIG. 9, the display panel 100 may include a substrate SUB, a buffer layer BF, a first active layer ACTL1, a first gate insulating layer GI1, a first gate layer GTL1, a second gate insulating layer GI2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, a second via layer VIA2, a pixel defining layer PDL, a light receiving element PD, and an encapsulation layer TFEL.

The first active layer ACTL1 may be disposed on the buffer layer BF. The first active layer ACTL1 may include a silicon-based material. For example, the first active layer ACTL1 may include (e.g., may be made of) a low-temperature polycrystalline silicon (LTPS). The first active layer ACTL1 may include a semiconductor area PACT1, a first electrode PSE1, and a second electrode PDE1 of the first sensor transistor PT1.

The first gate layer GTL1 may be disposed on the first gate insulating layer GI1. The first gate layer GTL1 may include the gate electrode PGE1 of the first sensor transistor PT1.

The second active layer ACTL2 may be disposed on the first interlayer insulating layer ILD1. The second active layer ACTL2 may include an oxide-based material. The second active layer ACTL2 may include a semiconductor area PACT2, a first electrode PDE2 of the second sensor transistor PT2, and a second electrode PSE2 of the second sensor transistor PT2.

The third gate layer GTL3 may be disposed on the third gate insulating layer GI3. The third gate layer GTL3 may include the gate electrode PGE2 of the second sensor transistor PT2. The gate electrode PGE2 of the second sensor transistor PT2 may be a portion of the reset signal line GRL.

The first source metal layer SDL1 may be disposed on the second interlayer insulating layer ILD2. The first source metal layer SDL1 may include a sensor connection electrode PCE and a first sensor node electrode NSE1. The sensor connection electrode PCE may electrically connect the reset voltage line VRL with the second electrode PSE2 of the second sensor transistor PT2. The first sensor node electrode NSE1 may electrically connect the first electrode PDE2 of the second sensor transistor PT2 with the gate electrode PGE1 of the first sensor transistor PT1.

The second source metal layer SDL2 may be disposed on the first via layer VIA1. The second source metal layer SDL2 may include a reset voltage line VRL and a second sensor node electrode NSE2. The second sensor node electrode NSE2 may electrically connect the sensor electrode PE with the first sensor node electrode NSE1.

The light receiving element PD may include a sensor electrode PE, a hole transporting layer HTL, a light receiving layer RCL, an electron transporting layer ETL, and a common electrode CAT. The sensor electrode PE may be disposed on the second via layer VIA2, and may be disposed at (e.g., in or on) the same layer as that of the pixel electrode AE of the light emitting element ED. The sensor electrode PE may overlap with one of a plurality of sensor areas PDA defined by the pixel defining layer PDL.

The hole transporting layer HTL may be disposed on the sensor electrode PE in the sensor area PDA, and may be disposed on the pixel defining layer PDL in the non-light-emitting area NEA. The hole transporting layer HTL may not be divided for each fingerprint sensor OPD, and may be implemented as a common layer of the entire pixel SP and the fingerprint sensor OPD.

The light receiving layer RCL may be disposed on the hole transporting layer HTL. The light receiving layer RCL may receive light emitted from the second light-emitting area EA2 and reflected by a fingerprint of a user. The light output from the light emitting element ED of the second light-emitting area EA2 may be reflected by the ridge or valley of the fingerprint, and the reflected light may reach the light receiving layer RCL. The light receiving element PD may convert energy of the light into an electric signal (e.g., a current or a voltage) formed between the sensor electrode PE and the common electrode CAT, and the converted electric signal may flow to the sensor node NS described above with reference to FIG. 8 as a reverse bias current. For example, when the light receiving element PD receives light, and thus, an electric field is formed between the sensor electrode PE and the common electrode CAT of the light receiving element PD, the current may flow to the light receiving element PD in proportion to the quantity of the light.

The electron transporting layer ETL may be disposed on the light receiving layer RCL in the sensor area PDA, and may be disposed on the hole transporting layer HTL in the non-light-emitting area NEA. The electron transporting layer ETL may not be divided for each fingerprint sensor OPD, and may be implemented as a common layer of the entire pixel SP and the fingerprint sensor OPD.

The common electrode CAT may be disposed on the electron transporting layer ETL. For example, the common electrode CAT may not be divided for each of the plurality of pixels SP, and may be implemented in the form of an electrode common to the entire pixel SP and the fingerprint sensor OPD. The common electrode CAT may be a transparent electrode, and may transmit light. The common electrode CAT may be electrically connected to the low potential line VSSL, and may receive a low potential voltage, a common voltage, or a cathode voltage.

The encapsulation layer TFEL may be disposed on the common electrode CAT to cover a plurality of light receiving elements PD. The encapsulation layer TFEL may include at least one inorganic layer to prevent or substantially prevent oxygen or moisture from being permeated into the plurality of light receiving elements PD. The encapsulation layer TFEL may include at least one organic layer to protect the plurality of light receiving elements PD from particles, such as dust.

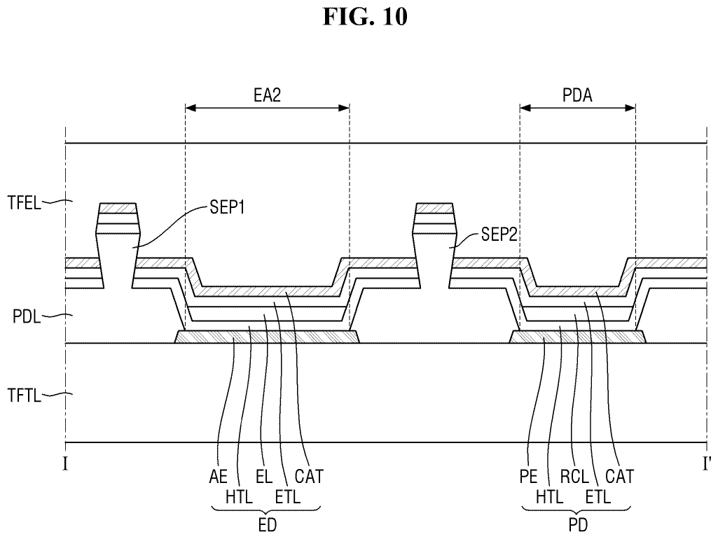

FIG. 10 is a cross-sectional view taken along the line I-I′ of FIG. 5.

Referring to FIG. 10, the light emitting element ED may include the pixel electrode AE, the hole transporting layer HTL, the light emitting layer EL, the electron transporting layer ETL, and the common electrode CAT. The light receiving element PD may include the sensor electrode PE, the hole transporting layer HTL, the light receiving layer RCL, the electron transporting layer ETL, and the common electrode CAT.

The pixel electrode AE may be disposed on the thin film transistor layer TFTL. The pixel electrode AE may overlap with one of the plurality of light-emitting areas EA defined by the pixel defining layer PDL.

The sensor electrode PE may be disposed on the thin film transistor layer TFTL, and may be disposed at (e.g., in or on) the same layer as that of the pixel electrode AE of the light emitting element ED. The sensor electrode PE may overlap with one of the plurality of sensor areas PDA defined by the pixel defining layer PDL.

The hole transporting layer HTL may be disposed on the pixel electrode AE in the light-emitting area EA, on the sensor electrode PE in the sensor area PDA, and on the pixel defining layer PDL in the non-light-emitting area NEA. The hole transporting layer HTL may not be divided for each of the pixels SP and the fingerprint sensor OPD, and may be implemented as a common layer of the entire pixel SP and the fingerprint sensor OPD. The hole transporting layer HTL may be cut by the first and second separation portions SEP1 and SEP2.

The light emitting layer EL may be disposed on the hole transporting layer HTL in the light-emitting area EA. For example, the light emitting layer EL may be an organic light emitting layer including (e.g., made of) an organic material, but the present disclosure is not limited thereto.

The light receiving layer RCL may be disposed on the hole transporting layer HTL in the sensor area PDA. The light receiving layer RCL may receive light emitted from the second light-emitting area EA2 and reflected by a fingerprint of a user. The light output from the light emitting element ED in the second light-emitting area EA2 may be reflected by the ridge or valley of the fingerprint, and the reflected light may reach the light receiving layer RCL.

The electron transporting layer ETL may be disposed on the light emitting layer EL in the light-emitting area EA, on the light receiving layer RCL in the sensor area PDA, and on the hole transporting layer HTL in the non-light-emitting area NEA. The electron transporting layer ETL may not be divided for each of the pixels SP and the fingerprint sensor OPD, and may be implemented as a common layer of the entire pixel SP and the fingerprint sensor OPD. The electron transporting layer ETL may be cut by the first and second separation portions SEP1 and SEP2.

The common electrode CAT may be disposed on the electron transporting layer ETL. For example, the common electrode CAT may not be divided for each of the plurality of pixels SP and the fingerprint sensor OPD, and may be implemented in the form of an electrode common to the entire pixel SP and the fingerprint sensor OPD. The common electrode CAT may be a transparent electrode, and may transmit light. The common electrode CAT may be cut by the first and second separation portions SEP1 and SEP2.

The first separation portion SEP1 may surround (e.g., around a periphery of) a portion of each of the first to third light-emitting areas EA1, EA2 and EA3. For example, a plurality of first separation portions SEP1 may surround (e.g., around a periphery of) a half or more of an edge of the second light-emitting area EA2, and the other portion of the edge of the second light-emitting area EA2 may be exposed toward its peripheral light-emitting area EA by first opening portions OP1. The first opening portion OP1 may be disposed between the first separation portions SEP1 adjacent to each other. A direction in which the light-emitting areas EA are adjacent to each other may be different from a direction in which the first opening portion OP1 is disposed. The first opening portion OP1 may not be disposed on the shortest distance between the adjacent light-emitting areas EA. For example, the first opening portion OP1 of each of the second light-emitting areas EA2 adjacent to each other in the X-axis direction may be disposed in the Y-axis direction with respect to a center of the second light-emitting area EA2. The first opening portion OP1 of each of the first and third light-emitting areas EA1 and EA3 adjacent to each other in the Y-axis direction may be disposed in the X-axis direction with respect to a center of each of the first and third light-emitting areas EA1 and EA3, or may be disposed in a diagonal direction between the X-axis and Y-axis directions. At least one first separation portion SEP1 may be disposed on the shortest distance between the adjacent light-emitting areas EA. At least one first separation portion SEP1 may be disposed on a virtual line connecting centers of the adjacent light-emitting areas EA to each other.

The first separation portion SEP1 may have an embossed shape protruded from the pixel defining layer PDL. The embossed shape of the first separation portion SEP1 may have a reverse tapered angle structure as shown in FIG. 10. An upper width of the first separation portion SEP1 may be greater than a lower width of the first separation portion SEP1. The first separation portion SEP1 may cut (e.g., may divide) the hole transporting layer HTL, the electron transporting layer ETL, and the common electrode CAT on the shortest distance between the adjacent light-emitting areas EA. The hole transporting layer HTL, the electron transporting layer ETL, and the common electrode CAT may not be cut (e.g., may not be divided) by the first opening portion OP1. The first separation portion SEP1 may cut the hole transporting layer HTL, the electron transporting layer ETL, and the common electrode CAT between the adjacent light-emitting areas EA, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

The second separation portion SEP2 may surround (e.g., around a periphery of) a portion of the sensor area PDA. For example, a plurality of second separation portions SEP2 may surround (e.g., around a periphery of) a half or more of an edge of the sensor area PDA, and the other portion of the edge of the sensor area PDA may be exposed toward its peripheral first and third light-emitting areas EA1 and EA3 by second opening portions OP2. The second opening portion OP2 may be disposed between the second separation portions SEP2 adjacent to each other. A direction in which the sensor area PDA and the second light-emitting areas EA2 are adjacent to each other may be different from a direction in which the second opening portion OP2 is disposed. The second opening portion OP2 may not be disposed on the shortest distance between the sensor area PDA and the second light-emitting area EA2, which are adjacent to each other. For example, when the sensor area PDA and the second light-emitting area EA2 are adjacent to each other in the Y-axis direction, the second opening portion OP1 may be disposed in the X-axis direction with respect to a center of the sensor area PDA. At least one second separation portion SEP2 may be disposed on the shortest distance between the sensor area PDA and the second light-emitting area EA2, which are adjacent to each other. At least one second separation portion SEP2 may be disposed on a virtual line connecting centers of the sensor area PDA and the second light-emitting area EA2, which are adjacent to each other, to each other.

A distance between the second separation portion SEP2 and the sensor area PDA may be shorter than a distance between the first separation portion SEP1 and the light-emitting area EA. Therefore, the second separation portion SEP2 may have an embossed shape protruded from the pixel defining layer PDL. The first and second separation portions SEP1 and SEP2 may have the same or substantially the same shape as each other. The embossed shape of the second separation portion SEP2 may have a reverse tapered angle structure as shown in FIG. 10. An upper width of the second separation portion SEP2 may be greater than a lower width of the second separation portion SEP2. The second separation portion SEP2 may cut (e.g., may divide) the hole transporting layer HTL, the electron transporting layer ETL, and the common electrode CAT on the shortest distance between the sensor area PDA and the second light-emitting area EA2, which are adjacent to each other. The hole transporting layer HTL, the electron transporting layer ETL, and the common electrode CAT may not be cut (e.g., may not be divided) by the second opening portion OP2. The second separation portion SEP2 may cut the hole transporting layer HTL, the electron transporting layer ETL, and the common electrode CAT between the sensor area PDA and the second light-emitting area EA2, which are adjacent to each other, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

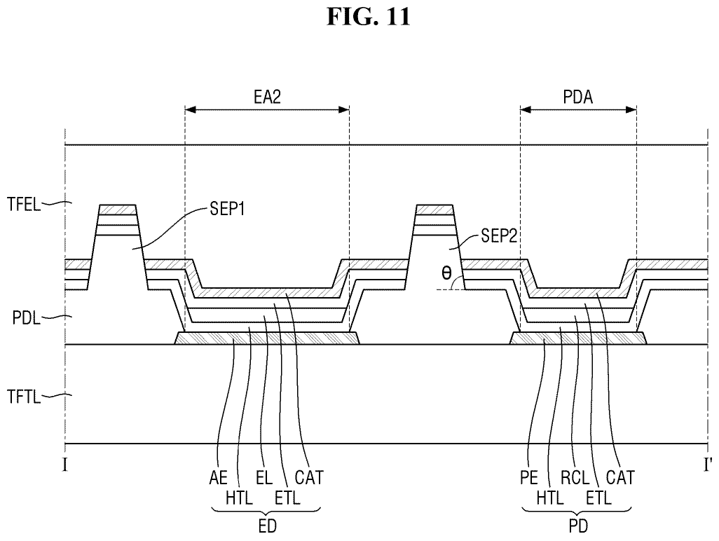

FIG. 11 is a cross-sectional view taken along the line I-I′ of FIG. 5. The display device of FIG. 11 may be different from the display device described above with reference to FIG. 10, in that shapes of the first and second separation portions SEP1 and SEP2 may be different. As such, the same or substantially the same elements as those described above may be briefly described, or redundant description thereof may not be repeated.

Referring to FIG. 11, the first separation portion SEP1 may have an embossed shape protruded from the pixel defining layer PDL. The embossed shape of the first separation portion SEP1 may have a tapered angle structure as shown in FIG. 11. An upper width of the first separation portion SEP1 may be smaller than a lower width of the first separation portion SEP1. For example, an angle between a side and a lower surface of the first separation portion SEP1 may be about 80° or more. In this case, the lower surface of the first separation portion SEP1 may be disposed at (e.g., in or on) the same plane as that of an upper surface of the pixel defining layer PDL. As the angle between the side and the lower surface of the first separation portion SEP1 is increased, the first separation portion SEP1 may more easily cut (e.g., divide) the hole transporting layer HTL, the electron transporting layer ETL, and the common electrode CAT. The first separation portion SEP1 may cut the hole transporting layer HTL, the electron transporting layer ETL, and the common electrode CAT between the adjacent light-emitting areas EA, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

A distance between the second separation portion SEP2 and the sensor area PDA may be shorter than a distance between the first separation portion SEP1 and the light-emitting area EA. Therefore, the second separation portion SEP2 may have an embossed shape protruded from the pixel defining layer. The first and second separation portions SEP1 and SEP2 may have the same or substantially the same shape as each other. The embossed shape of the second separation portion SEP2 may have a tapered angle structure as shown in FIG. 11. An upper width of the second separation portion SEP2 may be smaller than a lower width of the second separation portion SEP2. For example, an angle between a side and a lower surface of the second separation portion SEP2 may be about 80° or more. As the angle between the side and the lower surface of the second separation portion SEP2 is increased, the second separation portion SEP2 may more easily cut (e.g., divide) the hole transporting layer HTL, the electron transporting layer ETL, and the common electrode CAT. The second separation portion SEP2 may cut the hole transporting layer HTL, the electron transporting layer ETL, and the common electrode CAT between the sensor area PDA and the second light-emitting area EA2, which are adjacent to each other, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

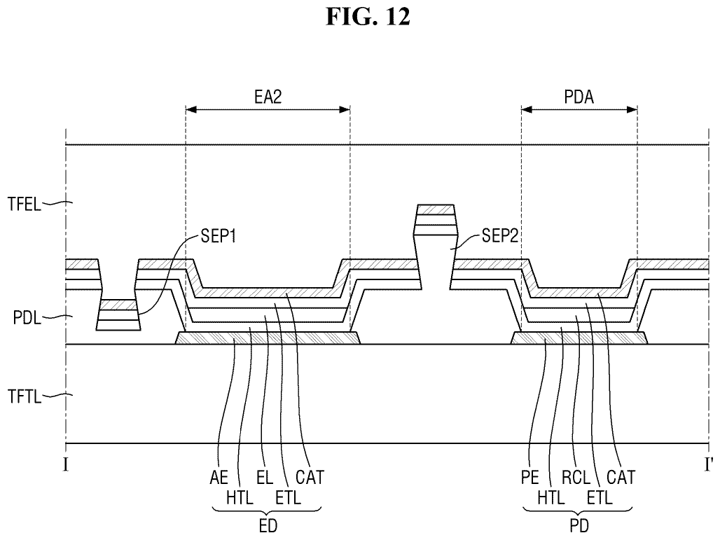

FIG. 12 is a cross-sectional view taken along the line I-I′ of FIG. 5. The display device of FIG. 12 may be different from the display device described above with reference to FIG. 10 and FIG. 11, in that the shapes of the first and second separation portions SEP1 and SEP2 may be different. As such, the same or substantially the same elements as those described above may be briefly described, or redundant description thereof may not be repeated.

Referring to FIG. 12, the first separation portion SEP1 may have an engraved shape that is recessed from the upper surface of the pixel defining layer PDL as shown in FIG. 12. An upper width of the first separation portion SEP1 may be smaller than a lower width of the first separation portion SEP1. The first separation portion SEP1 may cut (e.g., may divide) the hole transporting layer HTL, the electron transporting layer ETL, and the common electrode CAT between the adjacent light-emitting areas EA, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

A distance between the second separation portion SEP2 and the sensor area PDA may be shorter than a distance between the first separation portion SEP1 and the light-emitting area EA. Therefore, the second separation portion SEP2 may have an embossed shape protruded from the pixel defining layer PDL. The embossed shape of the second separation portion SEP2 may have a reverse tapered angle structure as shown in FIG. 12. An upper width of the second separation portion SEP2 may be greater than a lower width of the second separation portion SEP2. The second separation portion SEP2 may cut (e.g., may divide) the hole transporting layer HTL, the electron transporting layer ETL, and the common electrode CAT between the sensor area PDA and the second light-emitting area EA2, which are adjacent to each other, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

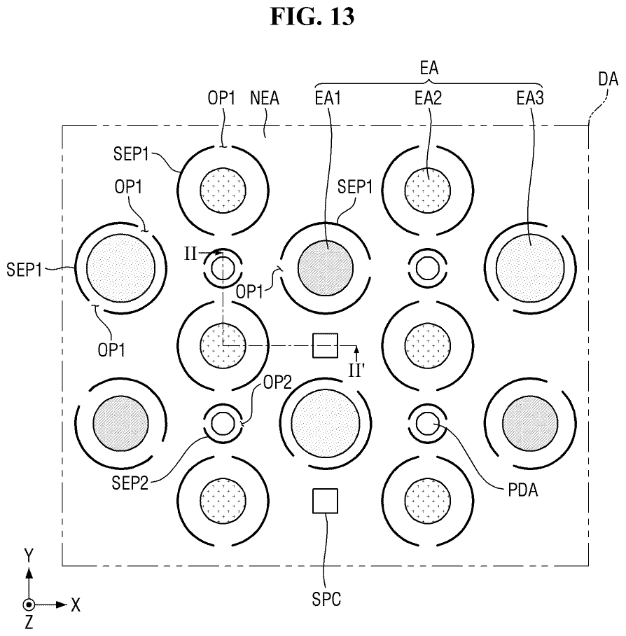

FIG. 13 is a plan view illustrating a display area of a display device according to another embodiment. The display device of FIG. 13 may further include a spacer SPC in the display device described above with reference to FIG. 5, and thus, the same or substantially the same elements as those described above may be briefly described, or redundant description thereof may not be repeated.

Referring to FIG. 13, a plurality of spacers SPC may be disposed from among the first to third light-emitting areas EA1, EA2 and EA3. For example, the spacer SPC may be disposed between the second light-emitting areas EA2 adjacent to each other in the X-axis direction, and may be disposed between the first and third light-emitting areas EA1 and EA3 adjacent to each other in the Y-axis direction, but the position of the spacer SPC on the plane (e.g., in a plan view) is not limited thereto. The spacer SPC may support a mask during a manufacturing process of the display device 10, and may improve a reliability by preventing or substantially preventing damage that may be caused to the light emitting element ED and the light receiving element PD.

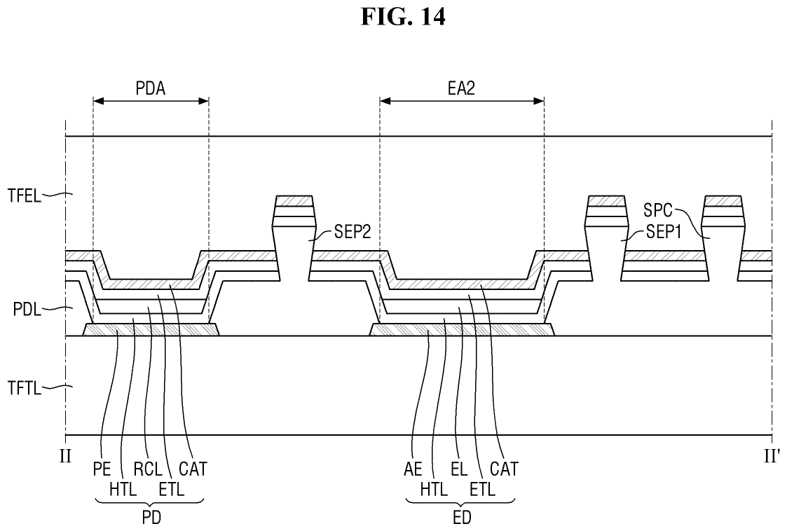

FIG. 14 is a cross-sectional view taken along the line II-II′ of FIG. 13.

Referring to FIG. 14, the spacer SPC may have an embossed shape protruded from the pixel defining layer PDL. The spacer SPC may have the same or substantially the same shape as that of the first and second separation portions SEP1 and SEP2. Therefore, because the spacer SPC and the first and second separation portions SEP1 and SEP2 may be formed in the same process as each other, the number of mask processes in the manufacturing process of the display device 10 may be minimized or reduced. The embossed shape of the spacer SPC may have a reverse tapered angle structure as shown in FIG. 14. The spacer SPC may cut (e.g., may divide) the hole transporting layer HTL, the electron transporting layer ETL, and the common electrode CAT.

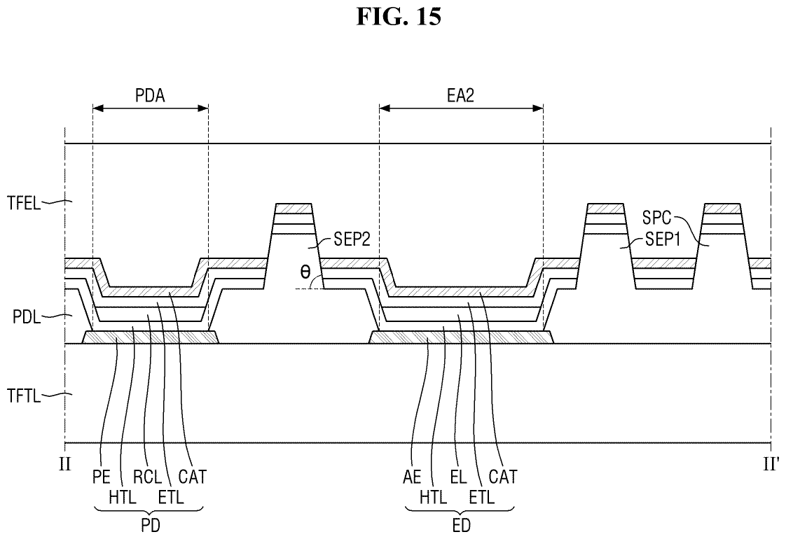

FIG. 15 is a cross-sectional view taken along the line II-II′ of FIG. 13. The display device of FIG. 15 may be different from the display device described above with reference to FIG. 14, in that the shapes of the spacer SPC and the first and second separation portions SEP1 and SEP2 may be different, and thus, the same or substantially the same elements as those described above may be briefly described, or redundant description thereof may not be repeated.

Referring to FIG. 15, the spacer SPC may have an embossed shape protruded from the pixel defining layer PDL. The spacer SPC may have the same or substantially the same shape as that of the first and second separation portions SEP1 and SEP2. Therefore, because the spacer SPC and the first and second separation portions SEP1 and SEP2 may be formed in the same process as each other, the number of mask processes in the manufacturing process of the display device 10 may be minimized or reduced. The embossed shape of the spacer SPC may have a tapered angle structure as shown in FIG. 15. An upper width of the spacer SPC may be smaller than a lower width of the spacer SPC. For example, an angle between a side and a lower surface of the spacer SPC may be about 80° or more. In this case, the lower surface of the spacer SPC may be disposed at (e.g., in or on) the same plane as that of the upper surface of the pixel defining layer PDL. The spacer SPC may cut (e.g., may divide) the hole transporting layer HTL, the electron transporting layer ETL, and the common electrode CAT.

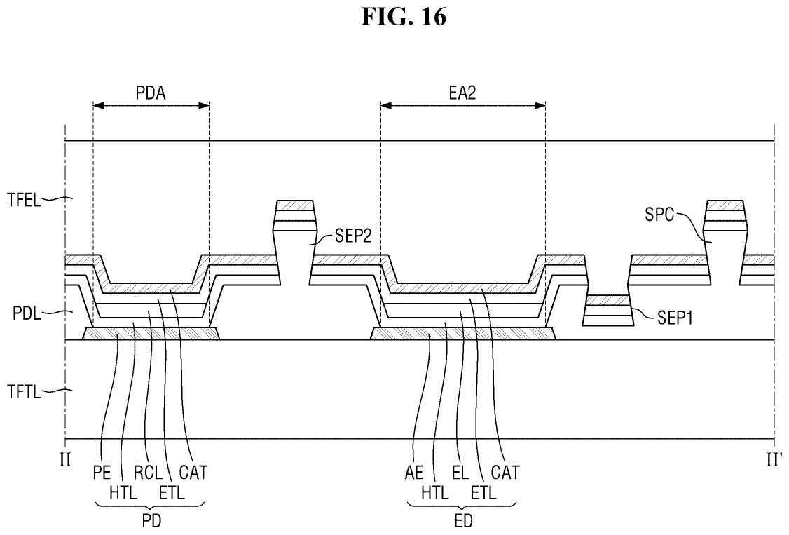

FIG. 16 is a cross-sectional view taken along the line II-II′ of FIG. 13. The display device of FIG. 16 may be different from the display device of FIG. 14, in that a shape of the first separation portion SEP1 may be different, and thus, the same or substantially the same elements as those described above may be briefly described, or redundant description thereof may not be repeated.

Referring to FIG. 16, the first separation portion SEP1 may have an engraved shape that is recessed from the upper surface of the pixel defining layer PDL. An upper width of the first separation portion SEP1 may be smaller than a lower width of the first separation portion SEP1. The first separation portion SEP1 may cut the hole transporting layer HTL, the electron transporting layer ETL, and the common electrode CAT between the adjacent light-emitting areas EA, thereby minimizing or reducing a leakage current flowing in the pixel SP and the fingerprint sensor OPD even in a high-resolution structure in which the pixels SP and the fingerprint sensor OPD are concentrated, and thus, a sensitivity of the fingerprint sensor OPD may be improved.

The spacer SPC may have an embossed shape protruded from the pixel defining layer PDL. The spacer SPC may have the same or substantially the same shape as that of the second separation portion SEP2. Therefore, because the spacer SPC and the second separation portion SEP2 may be formed in the same process as each other, the number of mask processes in the manufacturing process of the display device 10 may be minimized or reduced. The embossed shape of the spacer SPC may have a reverse tapered angle structure as shown in FIG. 16. The spacer SPC may cut (e.g., may divide) the hole transporting layer HTL, the electron transporting layer ETL, and the common electrode CAT.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a plurality of first light-emitting areas configured to emit light of a first color;
a plurality of second light-emitting areas configured to emit light of a second color different from the first color;
a plurality of third light-emitting areas configured to emit light of a third color different from the second color;
a sensor area between second light-emitting areas adjacent to each other in a first direction from among the plurality of second light-emitting areas;
a pixel defining layer defining the first, second, and third light-emitting areas, and the sensor area;
a plurality of first separation portions surrounding around a half or more of an edge of each of the first to third light-emitting areas; and
a plurality of second separation portions surrounding around a half or more of an edge of the sensor area, and located on a shortest distance between one of the second light-emitting areas and the senor area that are adjacent to each other.

2. The display device of claim 1, further comprising:
a first opening portion exposing an edge of each of the first, second, and third light-emitting areas toward at least one of the first, second, or third light-emitting areas adjacent thereto; and
a second opening portion exposing an edge of the sensor area toward at least one of the first or third light-emitting area adjacent thereto.

3. The display device of claim 2, wherein the first opening portion is not located on a shortest distance between adjacent light-emitting areas of the first, second, and third light-emitting areas.

4. The display device of claim 2, wherein the second opening portion is not located on a shortest distance between one of the second light-emitting areas and the senor area that are adjacent to each other.

5. The display device of claim 2, wherein the second opening portion is located in a second direction crossing the first direction with respect to a center of the sensor area.

6. The display device of claim 1, wherein the sensor area is located between the first and third light-emitting areas that are adjacent to each other in a second direction crossing the first direction.

7. The display device of claim 1, wherein a distance between the sensor area and the second separation portion is shorter than a distance between one of the first, second, or third light-emitting areas and the first separation portion.

8. The display device of claim 1, wherein each of the first and second separation portions has an embossed shape protruded from the pixel defining layer, and has a reverse tapered angle structure having an upper width greater than a lower width.

9. The display device of claim 1, wherein each of the first and second separation portions has an embossed shape protruded from the pixel defining layer, and has a tapered angle structure having an upper width smaller than a lower width, and
wherein an angle between a side and a lower surface of each of the first and second separation portions is 80° or more.

10. The display device of claim 1, wherein the first separation portion has an engraved shape recessed from an upper surface of the pixel defining layer, and the second separation portion has an embossed shape protruded from the upper surface of the pixel defining layer.

11. The display device of claim 1, further comprising:
a pixel electrode in each of the first, second, and third light-emitting areas;
a sensor electrode in the sensor area, and at the same layer as that of the pixel electrode;
a hole transporting layer on the pixel electrode and the sensor electrode;
a light emitting layer on the hole transporting layer in each of the first, second, and third light-emitting areas;
a light receiving layer on the hole transporting layer in the sensor area;
an electron transporting layer on the light emitting layer and the light receiving layer; and
a common electrode on the electron transporting layer.

12. The display device of claim 11, wherein the hole transporting layer, the electron transporting layer, and the common electrode are divided by the first and second separation portions.

13. The display device of claim 1, further comprising a spacer surrounded by the first, second, and third light-emitting areas, and having an embossed shape protruded from the pixel defining layer.

14. The display device of claim 13, wherein the spacer and the second separation portion are located at the same layer as each other and have the same shape as each other.

15. A display device comprising:
a plurality of first light-emitting areas configured to emit light of a first color;
a plurality of second light-emitting areas configured to emit light of a second color different from the first color, and adjacent to one another along a first direction and a second direction crossing the first direction;
a plurality of third light-emitting areas configured to emit light of a third color different from the second color, spaced from each of the plurality of second light-emitting areas in a diagonal direction between the first direction and the second direction, and spaced from the plurality of first light-emitting areas in the first direction and the second direction;
a sensor area surrounded by the first, second, and third light-emitting areas;
a plurality of first separation portions surrounding around a half or more of an edge of each of the first, second, and third light-emitting areas;
a first opening portion exposing the edge of each of the first, second, and third light-emitting areas toward at least one of the first, second, or third light-emitting areas adjacent thereto;
a plurality of second separation portions surrounding around a half or more of an edge of the sensor area; and
a second opening portion exposing the edge of the sensor area toward at least one of the first or third light-emitting areas adjacent thereto.

16. The display device of claim 15, wherein a direction in which adjacent light-emitting areas of the first, second, and third light-emitting areas are disposed and a direction in which the first opening portion is disposed based on a center of a corresponding light-emitting area are different from each other.

17. The display device of claim 15, wherein a direction in which the sensor area and the second light-emitting area are adjacent to each other and a direction in which the second opening portion is disposed based on a center of the sensor area are different from each other.

18. The display device of claim 15, wherein the first opening portion is not located on a shortest distance between adjacent light-emitting areas of the first, second, and third light-emitting areas.

19. The display device of claim 15, wherein the second opening portion is not located on a shortest distance between one of the second light-emitting areas and the senor area, which are adjacent to each other.

20. A display device of an electronic device comprising:
a plurality of first light-emitting areas configured to emit light of a first color;
a plurality of second light-emitting areas configured to emit light of a second color different from the first color;
a plurality of third light-emitting areas configured to emit light of a third color different from the second color;
a sensor area between second light-emitting areas adjacent to each other in a first direction from among the plurality of second light-emitting areas;
a pixel defining layer defining the first, second, and third light-emitting areas, and the sensor area;
a plurality of first separation portions surrounding around a half or more of an edge of each of the first to third light-emitting areas; and
a plurality of second separation portions surrounding around a half or more of an edge of the sensor area, and located on a shortest distance between one of the second light-emitting areas and the senor area that are adjacent to each other, wherein the electronic device is one of a mobile phone, a smart phone, a tablet personal computer (PC), a mobile communication terminal, an electronic diary, an electronic book, a portable multimedia player (PMP), a navigator, an ultra mobile PC (UMPC), a television, a laptop computer, a monitor, a signboard, a display of an Internet of things (IoT) device, or a wearable device, such as a smart watch, a watch phone, an eyeglasses display, or a head mounted display (HMD).
